(19) United States
(12) Patent Application Publication
(10) Pub. No.: US 2026/0305230 A1
(43) Pub. Date: Oct. 1, 2026

(54) BATCH SUBSTRATE PROCESSING FOR AREA SELECTIVE DEPOSITION

(71) Applicant: ASM IP Holding B.V., Almere (NL)

(72) Inventor: Dieter Pierreux, Pepingen (BE)

(21) Appl. No.: 19/629,339

(22) Filed: Mar. 26, 2026

Related U.S. Application Data
(60) Provisional application No. 63/780,559, filed on Mar. 31, 2025.

(51) Int. Cl. H10P 72/00; C23C 16/04; H10P 72/10; H10P 72/30

(52) U.S. Cl. CPC H10P 72/0454; C23C 16/042; H10P 72/0402; H10P 72/12; H10P 72/3218; H10P 72/3308

(57) ABSTRACT

The present invention relates to a substrate batch processing system, and to a method, for selectively forming a material on a first part of a surface of a substrate. The system comprises a first deposition module, comprising a first process chamber, for providing a passivation layer on said second part of the surface of the substrate, transfer apparatus configured for transferring, after formation of said passivation layer, the substrate from the first process chamber into a second process chamber and a second deposition module, comprising the second process chamber, for depositing the material on the first part of the surface of the substrate.

### CROSS-REFERENCE TO RELATED APPLICATIONS

This application claims priority to U.S. Provisional Patent Application Ser. No. 63/780,559 filed Mar. 31, 2025 titled BATCH SUBSTRATE PROCESSING FOR AREA SELECTIVE DEPOSITION, the disclosure of which is hereby incorporated by reference in its entirety.

### TECHNICAL FIELD OF THE INVENTION

The present invention relates to the field of semiconductor processing equipment, and more specifically to substrate batch processing systems for the area selective deposition of a material.

### BACKGROUND OF THE INVENTION

Area selective deposition, which is the selective deposition of materials onto specific parts of a substrate surface but not on other parts of the surface, is a critical process in semiconductor manufacturing and advanced material fabrication. This technique enables the precise patterning necessary for the production of integrated circuits and various microelectronic components. By controlling where material is deposited, manufacturers can build complex structures layer by layer, which is advantageous for device miniaturization and enhancing performance.

A known approach to achieve area selective deposition involves the use of passivation layers. In this approach, passivation layers are applied to certain areas of the substrate to inhibit material deposition on those areas. Areas not covered by the passivation layer, and on which material is to be deposited, may be called nucleation surfaces. When the material is provided over the surface, the passivation layer limits deposition of the material so that the material is deposited predominantly in the nucleation surface. As such, this approach allows deposition of the material to occur only on desired areas.

As device architectures become increasingly complex and demands for higher precision and quality intensify, improvements to existing selective deposition processes are called for. This is particularly true as these selective deposition techniques are scaled up and implemented in batch processing apparatus. Apart from an ever-existing need for increasing process efficiency, there is need for improved deposition quality and selectivity of these processes in batch processing systems.

### SUMMARY OF THE INVENTION

It is an objective of the present invention to provide good substrate batch processing systems and methods that address at least some of the above challenges.

The above objective is accomplished by a substrate batch processing systems and method according to the present invention.

It is an advantage of embodiments of the present invention that the different processes that are associated with different thermal budgets are performed in different process chambers, thereby increasing the thermal efficiency of the process.

It is an advantage of embodiments of the present invention that the use of separate process chambers prevents the passivation layer precursor from affecting the selective deposition chemistry. It is an advantage of embodiments of the present invention that the selectivity of the deposition process is improved by reducing cross-contamination.

In a first aspect, the present invention relates to a substrate batch processing system for selectively forming a material on a first part of a surface of a substrate, selectively with respect to a second part of the surface of the substrate. The substrate batch processing system comprises a first deposition module for providing a passivation layer on said second part of the surface of the substrate. The first deposition module comprises a first process chamber for receiving the substrate, a first heater configured for heating and maintaining a first process temperature in the first process chamber, and a first gas injector configured for providing, into the first process chamber, a first gas comprising a precursor for forming a passivation layer. The first deposition module further comprises a first controller configured to cause the first deposition module to provide the passivation layer on the second part of the surface of the substrate, selectively with respect to the first part. The substrate batch processing system further comprises a transfer apparatus configured for transferring, after formation of said passivation layer, the substrate from the first process chamber into a second process chamber. The substrate batch processing system further comprises a second deposition module for depositing the material on the first part of the surface of the substrate. The second deposition module comprises said second process chamber for receiving the substrate, a second heater configured for heating and maintaining a second process temperature in the second process chamber, and a second gas injector configured for providing, into the second process chamber, a second gas comprising a precursor to the material. The second deposition module further comprises a second controller configured to cause the second deposition module to form a layer of said material on the first part of the surface of the substrate, selectively with respect to the passivation layer on the second part.

In a second aspect, the present invention relates to a method for selectively forming a material on a first part of a surface of a substrate, selectively with respect to a second part of the surface of the substrate. The method comprises providing, in a first process chamber, at a first process temperature, a passivation layer on said second part of the surface of the substrate, selectively with respect to the first part. The method comprises, then, transferring the substrate from the first process chamber into a second process chamber. The method comprises, then, depositing, in the second process chamber, at a second process temperature, a layer of the material on the first part of the surface of the substrate, selectively with respect to the passivation layer on the second part.

In a third aspect, the present invention relates to a batch process comprising performing the method of embodiments of the second aspect on each of a plurality of substrates.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a vertical cross-sectional schematic representation of a substrate, wherein a passivation layer is provided on a second part of a surface of the substrate, in accordance with embodiments of the present invention.

FIG. 2 is a vertical cross-sectional schematic representation of the substrate, wherein a material is selectively deposited on a first part of a surface of the substrate, in accordance with embodiments of the present invention.

FIG. 3 is a vertical cross-sectional schematic representation of the substrate, wherein the passivation layer is selectively removed, in accordance with embodiments of the present invention.

FIG. 4 is a horizontal cross-sectional schematic representation of a substrate batch processing system in accordance with embodiments of the present invention.

FIG. 5 is a vertical cross-sectional schematic representation of a first processing zone, containing a first deposition module and a first wafer boat handling space, of the substrate batch processing system of FIG. 4, in accordance with embodiments of the present invention.

FIG. 6 is a vertical cross-sectional view of the first deposition module of the substrate batch processing system of FIG. 4, in accordance with embodiments of the present invention.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

In a first aspect, the present invention relates to a substrate batch processing system for selectively forming a material on a first part of a surface of a substrate, selectively with respect to a second part of the surface of the substrate. The substrate batch processing system comprises a first deposition module for providing a passivation layer on said second part of the surface of the substrate. The first deposition module comprises a first process chamber for receiving the substrate, a first heater configured for heating and maintaining a first process temperature in the first process chamber, and a first gas injector configured for providing, into the first process chamber, a first gas comprising a precursor for forming a passivation layer. The first deposition module further comprises a first controller configured to cause the first deposition module to provide the passivation layer on the second part of the surface of the substrate, selectively with respect to the first part. The first controller may be configured to execute instructions stored in a non-transitory computer readable medium so as to cause the first deposition module to form the passivation layer on the second part of the surface of the substrate. The substrate batch processing system further comprises a transfer apparatus configured for transferring, after formation of said passivation layer, the substrate from the first process chamber into a second process chamber. The substrate batch processing system further comprises a second deposition module for depositing the material on the first part of the surface of the substrate. The second deposition module comprises said second process chamber for receiving the substrate, a second heater configured for heating and maintaining a second process temperature in the second process chamber, and a second gas injector configured for providing, into the second process chamber, a second gas comprising a precursor to the material. The second deposition module further comprises a second controller configured to cause the second deposition module to form a layer of said material on the first part of the surface of the substrate, selectively with respect to the passivation layer on the second part. The second controller may be configured to execute instructions stored in a non-transitory computer readable medium so as to cause the second deposition module to form a layer of the material on the first part of the surface of the substrate.

In the state of the art, said providing of the passivation layer and said selective deposition of the material are typically performed in the same process chamber. Said providing of the passivation layer on the second part of the surface of the substrate is typically associated with a different thermal budget than said selective deposition of the material on the first part of the surface of the substrate. The two processes, therefore, have different systems requirements, for example, with respect to type and configuration of heaters, or with respect to a pressure that is to be maintained. Furthermore, wear and tear could accelerate due to frequent temperature cycling, potentially resulting in frequent maintenance and downtime. It is an advantage of embodiments of the present invention that these processes are performed in different process chambers so that optimized control of the process may be achieved, improving yield and quality of the process.

In addition, the inventor has found that, when the deposition of the passivation layer and the selective deposition of the material are performed in the same process chamber, the chemistries of the two processes may interfere, which may result in reduced selectivity of the deposition process. This may be particularly true if the passivation layer is a small molecular inhibitor layer. It is an advantage of embodiments of the present invention that cross-contamination between the different processes is prevented.

In embodiments, a surface clean step may take place before the passivation layer is provided. The surface clean step may be for cleaning the second part of the surface. The surface clean step may be for cleaning the first part of the surface. The surface clean step is preferably for cleaning both the first and the second part of the surface.

The surface clean step may comprise any technique for removing unwanted chemicals or contaminants from the surface. The surface clean step may, for example, comprise cleaning the surface by applying hydrofluoric acid to the surface for removing native oxides. The surface clean step may comprise megasonic cleaning or soft scrubbing for removing particles from the surface.

In embodiments, the surface clean step may be performed on the substrates before the substrates enter the first process chamber. The substrate batch processing system may comprise a substrate cleaning chamber adapted for cleaning the surface of the substrates. In embodiments, the substrate cleaning chamber comprises a spray cleaning module, e.g., a batch spray cleaning module, for applying a solution to the substrate surface for cleaning the surface. In embodiments, the substrate cleaning chamber comprises an immersion bath comprising a solution for batch immersion cleaning of the substrates. The substrates may be provided individually or in batch into the substrate cleaning chamber for cleaning of the substrate surfaces. The substrate cleaning chamber may optionally be in the same tool that comprises the first and second deposition modules, although this is not required.

For example, the substrates may be provided or introduced as cleaned substates into the substrate batch processing system.

In embodiments, the first process temperature may be different from the second process temperature. In embodiments, the second process temperature may be higher than the first process temperature. In some embodiments, the second process temperature may be lower than the first process temperature. The first process temperature may depend on the composition of the first gas comprising the precursor for forming the passivation layer. Typically, the first process temperature is adapted so that the precursor for forming the passivation layer is deposited on the second part of the surface so as to form the passivation layer. The first process temperature is typically adapted so that the first gas remains in the vapor-phase. The first heater may be configured for maintaining the first process temperature in the first process chamber for the duration of the process for providing of the passivation layer on the second part of the surface of the substrate. In embodiments, the first heater is controlled by the first controller.

The second process temperature may depend on the composition of the precursor to the material. Typically, the second process temperature is adapted so that the precursor for forming the material is deposited on the first part of the surface so as to form the material. The second process temperature is typically adapted so that the precursor to the material may be deposited or adsorbed or chemisorbed on the first part of the surface to form the material. The second process temperature may be maintained for the duration of the process for selective deposition of the material on the first part of the surface of the substrate.

In embodiments, the second controller may be configured for—after said material is deposited on the substrate—controlling the second heater so as to anneal the substrate in the second deposition module. In embodiments, said anneal may be performed by heating the second process chamber to an annealing temperature. In embodiments, the second heater may be configured for—after said material is deposited on the substrate—heating the second process chamber to the annealing temperature. In embodiments, the anneal may be a densification anneal. These embodiments may allow for densification, and improvement of the quality, of the deposited material.

In embodiments, the substrate may be any material upon which processes such as deposition, etching, or patterning may be performed. The substrate may comprise or be a wafer. For example, the substrate may comprise or be a wafer for use in semiconductor manufacturing or related industries. The substrate may comprise or be a semiconductor wafer, such as a silicon wafer, a gallium arsenide wafer, a silicon carbide wafer, a germanium wafer, or an indium phosphide wafer, although the invention is not limited thereto.

In embodiments, the selectivity of providing the passivation layer on the second part, selectively with respect to the first part, of the surface, may mean that more of the passivation layer is present on the second part than on the first part. In embodiments, said selectivity of providing the passivation layer on the second part, selectively with respect to the first part, of the surface, may mean that the passivation layer provided on the second part of the surface has an at least 2×, preferably at least 10×, more preferably at least 100×, as high areal density (i.e., mass per area) or thickness as the passivation layer, if present, on the first part of the surface. Preferably, substantially no passivation layer is provided on the first part of the surface. In embodiments, the passivation layer may be provided selectively on the second part, but substantially not on the first part, of the surface by any technique known in the art.

In embodiments, the passivation layer is deposited area-selectively on the second part of the surface, selectively with respect to the first part of the surface. For example, the first and second part of the surface may be different (e.g., their chemistry may be different), so that the passivation layer is preferentially formed on the second part of the surface. In embodiments, an etch-back step may be used to remove any passivation layer formed on the first part of the surface. The etch-back step may be performed substantially uniformly over the complete surface of the substrate, e.g., to both the first part of the surface and to the second part of the surface. Although said etch-back step may also remove some of the passivation layer provided on the second part of the surface, the second part may contain a thicker layer of the passivation layer than the first part of the surface, so that, after removal of substantially all of said passivation layer on the first part of the surface, the second part may still contain, or be covered with, the passivation layer.

In embodiments, patterning techniques, such as lithography, masking techniques, selective chemical modification techniques, or electrochemical techniques, may be employed for said selective formation of the passivation layer on the second part of the surface. In some embodiments, the passivation layer may be deposited uniformly on the first and second part of the surface. Subsequently, the passivation layer may be removed from the first part of the surface with any technique known in the art, such as a patterning or lithographic step. Thereby, the passivation layer is provided selectively on the second part of the surface.

In embodiments, the passivation layer may be formed of any type of material that provides a selectivity of deposition of the material on the first part of the material. The first part of the surface, substantially not comprising the passivation layer, may be called the nucleation surface. As is known to the skilled person, the difference in selectivity may originate from a wide range of effects. The difference in selectivity may be due to a lack of nucleation sites for the material on the passivation layer. The first part of the surface may contain more nucleation sites, so that the material preferentially nucleates or deposits on the first part of the surface. The difference in selectivity may be due to a repulsion between the passivation layer and the precursor to the material. Said repulsion may originate from electrostatic forces or may be chemical in nature, providing a barrier that inhibits deposition of the material on the passivation layer. The difference in selectivity may be due to chemical inertness of the passivation layer to the material, so that the material does substantially not react with the passivation layer, preventing deposition, e.g., chemical vapor deposition or chemisorption, of the material on the passivation layer.

In embodiments, the passivation layer may be adapted for providing more deposition of the material—e.g., more mass per area or moles per area or a thicker layer of said material—on the first part than on the second part of the surface. In embodiments, the passivation layer be adapted for providing a higher deposition rate of the material on the first part than on the second part of the surface. For example, the passivation layer may provide an at least 2×, preferably at least 10×, more preferably at least 100×, higher deposition rate of the material on the first part than on the second part of the surface. Thereby, the passivation layer may allow for area selective deposition of the material. Said selectivity of depositing the material on the first part, selectively with respect to the second part, of the surface, may correspond to an at least 2×, preferably at least 10×, more preferably at least 100×, thicker layer of said material on the first part than on the second part of the surface. Preferably, substantially no material is deposited on the passivation layer. Any of said material that is deposited on the passivation layer on the second part of the surface may be removed with an etch-back step. Although the etch-back step may also remove some of the material deposited on the first part of the surface, the first part may contain—as a result of the selective deposition—a thicker layer of the material than the second part of the surface, so that, after removal of substantially all of said material on the second part of the surface, the first part may still contain a layer of said material.

In embodiments, the first deposition module may be arranged for depositing the passivation layer by vapor deposition, e.g., physical vapor deposition or chemical vapor deposition. The first gas contains a precursor to the passivation layer, e.g., a precursor to components, or molecules, of the passivation layer. The precursor for forming the passivation layer may contain the components, or molecules, of the passivation layer. The precursor may form, on deposition of the precursor, the components, or molecules, of the passivation layer.

In some embodiments, multiple precursors are provided for forming the passivation layer. In some embodiments, the first deposition module may comprise a plurality of first gas injectors, each for providing a first gas comprising a precursor for forming the passivation layer. As such, a plurality of first gases, optionally provided by different first gas injectors, may be provided into the first process chamber for forming the passivation layer. In these embodiments, the different first gases may provide different precursors for forming the passivation layer. The different precursors may be for providing different components of the passivation layer. In these embodiments, the different gases may be provided simultaneously, or may be provided cyclically and sequentially one after the other.

In embodiments, the passivation layer may be a self-assembled monolayer. In these embodiments, the precursor for forming a passivation layer may comprise molecules for forming the self-assembled monolayer. Examples of molecules that may be used for forming the self-assembled monolayer are thiols, which may be used, e.g., for selective deposition on SiO with respect to copper or cobalt. The molecules for forming the self-assembled monolayer may be provided into the first process chamber via the first gas injector and be deposited or provided selectively on the second part of the surface, where the molecules self-assemble to form the self-assembled monolayer.

In embodiments, the passivation layer may be formed by a directed self-assembly technique. In these embodiments, the passivation layer may be formed selectively on the second part of the surface by self-assembly of molecules for forming the self-assembled monolayer, wherein the molecules may be guided, e.g., by surface topography and/or surface chemical patterning, so that the self-assembled monolayer is selectively formed on the second part of the surface.

In embodiments, the passivation layer may be a small molecule inhibitor layer. In these embodiments, the precursor for forming a passivation layer may comprise molecules for forming the small molecule inhibitor layer. An example of a molecule that may be used for forming the small molecule inhibitor layer is N,N-Dimethyltrimethylsilylamine (DMATMS), which may be used for passivating SiO. The molecules for forming the small molecule inhibitor layer may be provided into the first process chamber via the first gas injector and be provided selectively on the second part of the surface where the molecules form the small molecule inhibitor layer.

The first part of the surface may be, for example, a metal surface, a semi-metal surface, a metal oxide surface, a surface formed of a semiconductor material, or a dielectric surface. The second part of the surface may be, for example, a metal surface, a semi-metal surface, a metal oxide surface, a surface formed of a semiconductor material, or a dielectric surface. The first part of the surface may be formed of the same material as the second part of the surface. The first part of the surface may be formed of a different material than the second part of the surface.

In embodiments, the first controller is adapted for controlling the first gas injector. The first gas injector may be fluidically coupled to a first source, which may be a precursor vessel. The first source may contain the precursor for forming the passivation layer, which may be stored in the first source in a liquid, gas or solid state. The first source may comprise an inlet for providing a carrier gas—typically an inert carrier gas, such as N₂, He or Ar—into the first source for carrying the first gas or the precursor to the passivation layer, in the vapor-phase, through an outlet of the first source, to the first gas injector. The first gas injector may contain a first valve. The first controller may be configured for opening the valve for providing the first gas into the first process chamber. The first controller may be configured for closing the first valve for stopping providing the first gas into the first process chamber.

The first deposition module may comprise heaters, that may be operated by the first controller, for keeping the first gas at or above the volatilization temperature so as to prevent undesirable condensation in the valves, filters, conduits, and other components associated with delivering the first gas into the first process chamber. A heater may be provided for heating the first source and additional heaters may be provided for heating the various valves and gas flow lines between the first source and the first process chamber, to prevent condensation and deposition of the first gas on such components. Gas-conveying components between the first source and the first process chamber may be provided in which the temperature is maintained above the volatilization temperature of the first gas (i.e., “hot zone”).

In embodiments, the first deposition module further comprises a device for purging the first process chamber, such as a device for performing inert gas purging on the first process chamber or a device for vacuum pumping the first process chamber. The first controller may be configured for activating said purging device to purge the first process chamber before the first gas is provided in the first process chamber. The first controller may be configured to purge the first process chamber after formation of the passivation layer to remove the first gas from the first process chamber. For example, the first process chamber may be purged before the substrates are moved out of the first process chamber, to be moved to the second process chamber, to prevent that the first gas could contaminate any parts of the system outside of the first process chamber. The first controller may be configured and programmed to purge the first process chamber after closing of the first valve. The controller may be configured and programmed to purge the first process chamber after closing of the first valve and before moving the substrates from the first process chamber to the second process chamber.

In embodiments, the second deposition module may be arranged for depositing the material by vapor deposition, such as physical vapor deposition or chemical vapor deposition. In embodiment, the second deposition module may be arranged for depositing the material by cyclical chemical vapor deposition, such as by atomic layer deposition.

The precursor to the material may contain the components, or molecules, of the material to be deposited on the first part of the surface. The precursor to the material may form on deposition, e.g., on chemisorption on the surface, the components, or molecules, of the material to be deposited on the first part of the surface. In some embodiments, multiple gases including the second gas, optionally provided by different gas injectors, may be provided into the second process chamber for depositing the material on the first part of the surface. In these embodiments, the different gases may provide different precursors for the material, which is for example the case in cyclic chemical vapor deposition, such as in atomic layer deposition. In these embodiments, the different gases may be provided simultaneously, or may be provided cyclically and sequentially one after the other.

The material that is deposited on the first part of the surface may be any type of material that may be deposited selectively on the first part of the surface with respect to the second part of the surface, i.e., with respect to the passivation layer on the second part of the surface. It is an advantage of embodiments of the present invention that a wide range of materials may be deposited selectively on the first part of the surface. The material deposited on the first part of the surface may, for example, be a dielectric material or a metallic material. The material deposited on the first part of the surface may, for example, be an oxide or a nitride.

In embodiments, the second controller is adapted for controlling the second gas injector. The second gas injector may be fluidically coupled to a second source, which may be a precursor vessel. The second source may contain the precursor to the material, which may be stored in the second source in a liquid, gas or solid state. The second source may comprise an inlet for providing a carrier gas into the second source for carrying the second gas or the precursor to the material, in the vapor-phase, through an outlet of the second source, to the second gas injector. The second controller may be configured for opening the valve for providing the second gas into the second process chamber. The second controller may be configured for closing the second valve for stopping providing the second gas into the second process chamber.

The second deposition module may comprise heaters, that may be operated by the second controller, for keeping the second gas at or above the volatilization temperature so as to prevent undesirable condensation in the valves, filters, conduits, and other components associated with delivering the second gas into the second process chamber. A heater may be provided for heating the second source and additional heaters may be provided for heating the various valves and gas flow lines between the second source and the second process chamber, to prevent condensation and deposition of the second gas on such components. Gas-conveying components between the second source and the second process chamber may be provided in which the temperature is maintained above the volatilization temperature of the second gas (i.e., “hot zone”).

In embodiments, the second deposition module further comprises a device for purging the second process chamber, such as a device for performing inert gas purging on the second process chamber or a device for vacuum pumping the second process chamber. The second controller may be configured for activating said purging device to purge the second process chamber before the second gas is provided in the second process chamber. The second controller may be configured and programmed to purge the second process chamber after formation of the passivation layer to remove the second gas from the second process chamber. For example, the second process chamber may be purged before the substrates are moved out of the second process chamber, to prevent that the second gas could contaminate any parts of the system outside of the second process chamber. The second controller may be configured and programmed to purge the second process chamber after closing of the second valve. The controller may be configured and programmed to purge the second process chamber after closing of the second valve and before moving the substrates out of the second process chamber.

After providing the material on the first part of the surface, the passivation layer may be removed from the second part of the surface. Said removal is typically performed without removing the material on the first part of the surface. This may be performed in the second process chamber, or the substrates may be moved to another process chamber where the passivation layer may be removed. For example, the passivation layer may be removed by a thermal treatment, or an etching technique such as plasma etching or chemical etching. However, removal of the passivation layer is not essential. For example, the passivation layer may be retained on the second part of the surface.

In embodiments, the first process chamber may be a batch reactor. In embodiments, the second process chamber may be a batch reactor. The first and second process chamber may be part of a cluster tool in which different processes are performed to form an integrated circuit. The first deposition module is at least for providing the passivation layer, but may in addition be used for further process steps. The second deposition module is at least for depositing the material on the first part of the surface, and optionally for annealing the substrate after depositing said material, but may in addition be used for further process steps. Indeed, various steps of a vapor deposition method can be performed within a single process chamber, or they can be performed in multiple process chambers, such as process chambers of a cluster tool, or deposition stations of a multi-station processing chamber.

In embodiments, the first and/or second process chamber may be a semiconductor processing apparatus process chamber. In embodiments, the first and/or second process chamber may be a flow-type reactor, such as a cross-flow reactor. In embodiments, the first and/or second process chamber may be a showerhead reactor. In embodiments, the first and/or second process chamber may be a space-divided reactor. In embodiments, the first and/or second process chamber may be a single wafer atomic layer deposition reactor. In embodiments, the first and/or second process chamber may be a high-volume manufacturing single wafer atomic layer deposition reactor.

In preferred embodiments, the first and/or second process chamber may be a batch reactor for processing multiple substrates simultaneously. In preferred embodiments, the first process chamber is a vertical furnace process chamber. In preferred embodiments, the second process chamber is a vertical furnace process chamber.

Typically, the first and second process chamber are located in a same processing tool. This provides a compact integrated system and may result in good efficiency of the process. In addition, contact of the substrates with any contaminants that may affect the substrates, which may in particular be provided to the substrate when the substrates are moved between different tools, may be limited. Preferably, the substrates are moved, within the same tool, from the first deposition module into the second deposition module, or from the first process chamber into the second process chamber, without loading or moving the substrates in cassettes between the first and second process chamber. Cassettes are typically used to transfer substrates between different tools, and may hold a plurality of substrates. Within the context of the present invention, the cassette may be any type of cassette, such as a front-opening unified pod (FOUP) for holding specifically 300 mm wafers or a cassette for holding smaller wafers. However, the processes of the present invention may be particularly sensitive towards contaminants such as oxygen, so that such a transfer via cassettes between different tools, by use of such cassettes, is unwanted.

In embodiments, the first process chamber is associated with a first wafer boat for holding a plurality of substrates, and the second process chamber is associated with a second wafer boat for holding a plurality of substrates, wherein the transfer apparatus comprises a wafer handling robot adapted for transferring substrates one by one, wherein the transfer apparatus is configured for, for each substrate, after providing said passivation layer on the substrate in the first processing chamber, transferring the substrate individually from the first wafer boat to the second wafer boat.

In embodiments, the substrate batch processing system may comprise a first wafer boat handling space adjacent, e.g., underneath, the first deposition module, in particular, adjacent, e.g., underneath, the first process chamber. In embodiments, the wafer handling robot may be configured for—before the passivation layer is provided—transferring the substrates one by one into the first wafer boat located in the first wafer boat handling space. Said transfer may be from, for example, a cassette or from another wafer boat. Subsequently, the first wafer boat may be moved, e.g., lifted, into the first process chamber for said providing of the passivation layer. After said passivation layer is provided, the first wafer boat may be moved, e.g., lowered, from the first process chamber into the first wafer boat handling space. In embodiments, the first wafer boat handling space may comprise a first wafer boat lift assembly adapted for said moving (e.g., lifting or lowering) of the first wafer boat between the first wafer boat handling space and the first process chamber.

Subsequently, said transfer—by the wafer handling robot—of the substrates from the first wafer boat to the second wafer boat may be performed. In embodiments, the wafer handling robot is located in a wafer handling space, coupled to the first wafer boat handling space and to the second wafer boat handling space.

In embodiments, the substrate batch processing system may comprise a second wafer boat handling space adjacent, e.g., underneath, the second deposition module, in particular, adjacent, e.g., underneath, the second process chamber. After the substrates have been transferred into the second wafer boat, the second wafer boat may be moved, e.g., lifted, into the second process chamber for said deposition of the material. After said material is deposited, the second wafer boat may be moved, e.g., lowered, from the second process chamber into the second wafer boat handling space. In embodiments, the second wafer boat handling space may comprise a second wafer boat lift assembly adapted for said moving (e.g., lifting or lowering) of the second wafer boat between the second wafer boat handling space and the second process chamber.

In alternative embodiments, the first process chamber may be adapted for receiving a substrate carrier supporting a plurality of substrates and for providing the passivation layer selectively on the second part of the surface of each substrate of the plurality of substrates, wherein the transfer apparatus is configured for transferring, after formation of said passivation layer, the substrate carrier from the first process chamber into a second process chamber, and wherein the second process chamber is adapted for receiving the substrate carrier and for depositing the material selectively on the first part of the surface of each substrate of the plurality of substrates.

The substrate carrier may, in these embodiments, be transferred as a whole from the first process chamber to the second process chamber. As such, the plurality of substrates may, in these embodiments, be transferred together, instead of one by one. For example, the substrate carrier may be a wafer boat, and the first and second process chamber may be associated with, or coupled to, a same, common wafer boat handling space. In these embodiments, the wafer boat may first be moved, e.g., lifted, from the common wafer boat handling space into the first process chamber. After providing the passivation layer, the wafer boat may be moved, e.g., lowered, from the first process chamber into the common wafer boat handling space. Subsequently, the wafer boat may be moved, e.g., lifted, from the common wafer boat handling space into the second process chamber for said deposition of the material. These embodiments may have the advantage of process efficiency.

In embodiments, the system may be adapted so that said transfer of the substrate from the first process chamber into the second process chamber is performed through an inert atmosphere. Preferably, said transfer is entirely through said inert atmosphere. In embodiments, said inert atmosphere may be a H₂ atmosphere. In embodiments, said inert atmosphere may be a nitrogen atmosphere or a noble gas atmosphere. These gases may provide an effective inert environment. In embodiments, the first wafer boat handling space contains the inert atmosphere. In embodiments, the second wafer boat handling space contains the inert atmosphere. In embodiments, the common wafer boat handling space contains the inert atmosphere. In embodiments, the wafer handling space contains the inert atmosphere.

The atmosphere within the first and second process chamber may depend on the specific processes that are performed in the first and second process chamber. The atmosphere within the first process chamber may contain an inert carrier gas (e.g., He, N₂ or Ar) and the first gas provided by the first gas injector. The atmosphere within the second process chamber may contain an inert carrier gas and the second gas provided by the second gas provided by the gas injector.

The first controller and the second controller may be the same controller. The first controller and the second controller may be separate controllers. The first controller may comprise a plurality of sub-controllers for executing different functions of the first controller (e.g., controlling the first gas injector for providing the first gas and/or controlling the first heater for heating and maintaining the first process temperature in the first process chamber). The first controller may contain instructions stored in a non-transitory computer readable medium for executing the different functions of the first controller. The second controller may comprise a plurality of sub-controllers for executing different functions of the second controller (e.g., controlling the second gas injector for providing the second gas and/or controlling the second heater for heating and maintaining the second process temperature in the first process chamber). The second controller may contain instructions stored in a non-transitory computer readable medium for executing the different functions of the second controller.

Any features of any embodiment of the first aspect may be independently as correspondingly described for any embodiment of any of the other aspects of the present invention.

In a second aspect, the present invention relates to a method for selectively forming a material on a first part of a surface of a substrate, selectively with respect to a second part of the surface of the substrate. The method comprises providing, in a first process chamber, at a first process temperature, a passivation layer on said second part of the surface of the substrate, selectively with respect to the first part. The method comprises, then, transferring the substrate from the first process chamber into a second process chamber. The method comprises, then, depositing, in the second process chamber, at a second process temperature, a layer of the material on the first part of the surface of the substrate, selectively with respect to the passivation layer on the second part.

The first and second process chamber are preferably part of the same tool or system. The substrate is preferably moved from the first process chamber to the second process chamber via an inert atmosphere. In other words, preferably, an inert transfer is provided between the first and second process chamber.

The method is preferably performed in a substrate batch processing system in accordance with embodiments of the first aspect of the present invention.

Any features of any embodiment of the second aspect may be independently as correspondingly described for any embodiment of any of the other aspects of the present invention.

In a third aspect, the present invention relates to a batch process comprising performing the method of embodiments of the second aspect on each of a plurality of substrates.

Any features of any embodiment of the third aspect may be independently as correspondingly described for any embodiment of any of the other aspects of the present invention.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

The present invention relates to substrate batch processing systems, and methods, for depositing a material on a first part of a surface of a substrate.

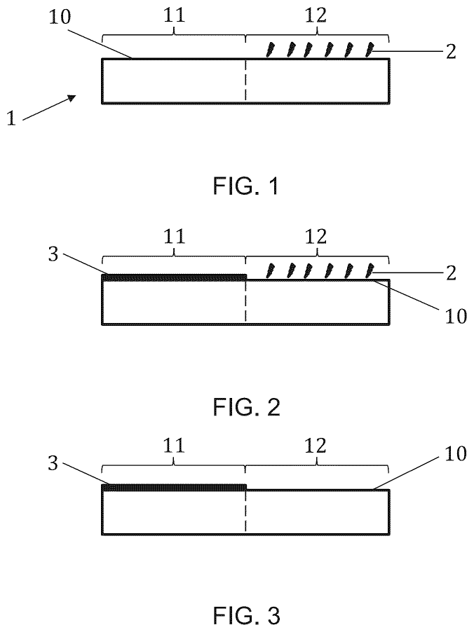

Reference is made to FIG. 1. To allow selective deposition of the material on the first part 11 of the surface 10 of the substrate 1, selectively with respect to the second part 12 of the surface 10 of the substrate 1, a passivation layer 2 is provided on the second part 12 of the surface 10 of the substrate. Typically, the first part 11 of the surface 10 contains no passivation layer 2.

Reference is made to FIG. 2. The passivation layer 2 may limit the deposition of the material 3 on the second part 12 of the surface 10. By the provision of the passivation layer 2, the deposition amount, or the deposition rate, of the material on the first part 11 of the surface 10 may be higher than the deposition rate of the material on the second part 12 of the surface 10.

Reference is made to FIG. 3. After deposition of the material 3 on the first part 11 of the surface 10, the passivation layer may optionally be removed from the second part 12 of the surface 10 while retaining the deposited material 3 on the first part 11 of the surface 10.

In the present invention, said provision of the passivation layer is performed in a different deposition module than said deposition of the material.

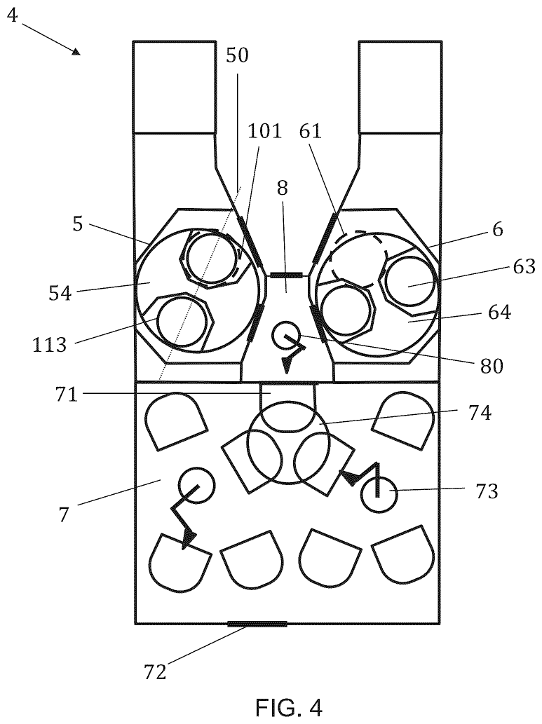

FIG. 4 is a schematic horizontal cross-sectional view of an exemplary substrate batch processing system 4 in accordance with embodiments of the present invention, for batch processing of a plurality of substrates. The substrate batch processing system 4 contains a first processing zone 5 comprising a first deposition module 101 (indicated by the dashed-lined circle) for providing a passivation layer on said second part of the surface of the substrates. The substrate batch processing system 4 contains a second processing zone 6 comprising a second deposition module 61 (indicated by the dashed-lined circle) for depositing the material on the first part of the surface of the substrates.

The substrate batch processing system 4 further contains transfer apparatus configured for transferring, after formation of said passivation layer, each substrate from the first deposition module 101 into the second deposition module 61, in particular, from a first process chamber of the first deposition module 101 into a second process chamber of the second deposition module 61.

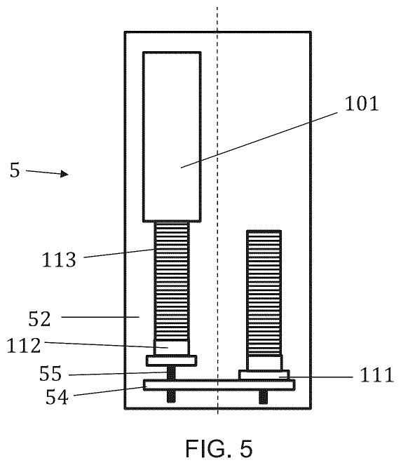

Simultaneous reference is made to FIG. 5, which is a vertical cross-sectional view of the first deposition module 5, along the dotted line 50 in FIG. 4. In the example illustrated, the first processing zone 5 comprises a first wafer boat handling space 52 adjacent, e.g., underneath, the first deposition module 101. In the example illustrated, the wafer boat handling space 52 comprises multiple first wafer boats 113. The first wafer boats 113 are located on a rotatable disc 54 comprising, for each first wafer boat 113, a first wafer boat lift assembly 55. Although the present example is concerned with wafer boats, in embodiments of the present invention, other types of substrate carriers could be used.

Substrates or wafers to be processed in accordance with embodiments of the present invention may be introduced into the substrate batch processing system 4 contained in cassettes 71, e.g., FOUPS. Such cassettes 71 may contain, and are typically used for transporting, a plurality of said substrates or wafers between different systems or tools. Said cassettes 71 may be introduced into the substrate batch processing system 4 through an entrance 72 to a cassette handling space 7. The cassette handling space 7 may contain transfer apparatus, including cassette handling robots 73 and a cassette storage carousel 74, for moving the cassettes.

The cassette handling space 7 is coupled to a wafer handling space 8 containing a wafer handling robot 80. The transfer apparatus of the cassette handling space 7 may be adapted for moving one of the cassettes 71 to a location from which the substrates may be moved by the wafer handling robot 80, e.g., to a port between the cassette handling space 7 and the wafer handling space 8. The wafer handling robot 80 may be configured for transferring the substrates one by one, i.e., individually, from said cassette 71 into a first wafer boat 113 located in the first wafer boat handling space 52 positioned for receiving the substrates. This may be performed until each substrate receiving position of the first wafer boat 113 contains a substrate.

Subsequently, the rotatable disc 54 may be rotated for positioning the first wafer boat 113 underneath the first deposition module 101. The first wafer boat 113 may be lifted, by the first wafer boat lift assembly 55, into the first process chamber of the first deposition module 101 for said providing of the passivation layer.

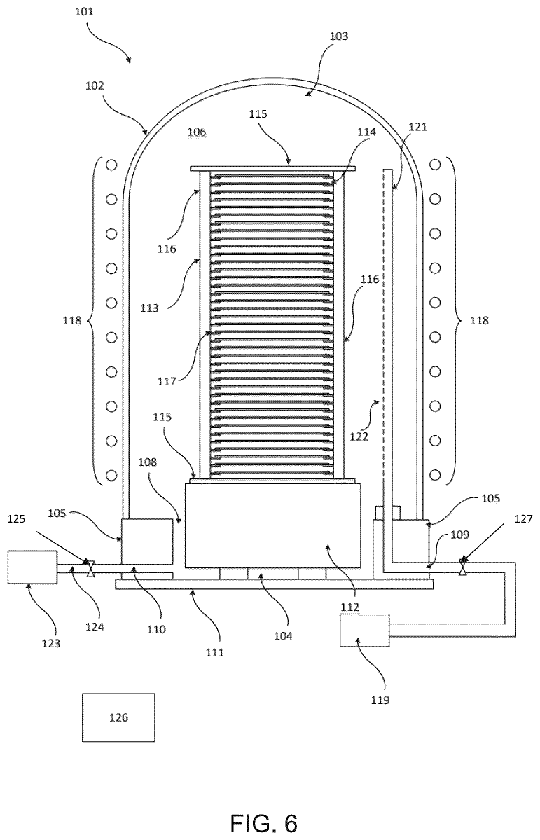

Simultaneous reference is made to FIG. 6, which is a vertical cross-sectional view of the first deposition module 101 that is in accordance with embodiments of the present invention. In the present example, the first process chamber 102 is generally bell jar shaped, having a closed top end 103, a closable bottom end 104, and an interior space 106. The first deposition module 101 may be a vertical furnace. The first process chamber 102 may accordingly extend in a vertical direction between the top end 103 and the bottom end 104. The first deposition module 101 may comprise a flange 105 for at least partially supporting the first process chamber 102 at the bottom end 104. The flange 105 may be generally circular in shape as viewed along the vertical direction. The flange 105 may comprise a central opening 108 and one or more gas inlets 109 for providing the first gas for forming the passivation layer into the interior space 106 of the first process chamber 102. The flange may comprise one or more gas outlets 110 for removing gas from the interior space 106, e.g., for purging any unreacted first gas, and/or any vapor-phase reaction products, from the interior space 106 of the first process chamber 102. The flange 105 may be configured to partially close off the bottom end 104 of the first process chamber 102.

In the present example, the first deposition module 101 comprises a doorplate 111 configured to at least partially close off the bottom end 104 of the first process chamber 102. The doorplate 111 may support a pedestal 112 thereon. The pedestal 112 may be configured to support the first wafer boat 113. The pedestal 112 and the first wafer boat 113 may be inserted into and removed from the reaction chamber 102 through the bottom end 104 by moving the doorplate 111 in a vertical direction. In some embodiments, no pedestal may be provided and the first wafer boat 113 may be supported directly on the doorplate 111.

In the present example, the first wafer boat 113 is configured to support a plurality of substrates 114 therein. The plurality of substrates 114 may be spaced apart in a vertical direction. The first wafer boat 113 may comprise two end plates 115 spaced apart by a plurality of support rods 116. The plurality of support rods 116 may comprise a plurality of sets of slots 117 or projections for supporting the plurality of substrates, each set of slots 117 or projections being spaced apart from the other sets of slots 117 or projections in the vertical direction. Each set of slots 117 or projections being at a same vertical position forms a respective substrate receiving position.

The first deposition module 101 comprises a first heater for heating the first process chamber 102 and thereby heating the interior space 106, for example in the form of heating coils 118 disposed around an outer surface of the first process chamber 102.

The first deposition module 101 comprises at least one gas inlet 109 in the flange 105 for providing the first gas to the interior space 106 of the first process chamber 102. The at least one gas inlet 109 may each be connected to one or more respective gas sources 119. The gas sources 119 may include process gas sources and purge gas sources. In particular, the gas sources 119 may comprise a first gas source 119 for the first gas. The gas sources 119 may be connected to the same gas inlet 109 or to different gas inlets 109. The gas inlets 109 may be categorized according to the type of gas to be provided therethrough; for example, the flange 105 may comprise one or more process gas inlets and one or more purge gas inlets.

The exemplary first deposition module 101 comprises at least one gas injector 121, each in fluid communication with a respective gas inlet 109. The first deposition module 101 may comprise the same number of injectors 121 as gas inlets 109, or may comprise fewer injectors 121 than gas inlets 109, that is, one or more gas inlets 109 may not be connected to an injector 121. In the present example, the injector 121 or each of the injectors 121 may extend in a vertical direction within the reaction chamber 102. In the present example, the injector 121 or each of the injectors 121 may comprise a series of holes 122 through which gas may flow into the first process chamber 102, the holes 122 being spaced apart in a vertical direction.

The first deposition module 101 comprises at least one gas outlet 110 in the flange 105 for removing a gas or gases from the interior space 106 of the first process chamber 102. The at least one gas outlet 110 may be in fluid communication with a vacuum pump 123 via an exhaust gas line 124, which may be used for purging of the first process chamber 102.

The first deposition module 101 may comprise a first controller 126 which may be configured to control various elements of the first deposition module 101. The first controller 126 may comprise a memory for storing, for example, program instructions, setpoint values, characterisation data, and other data. The first controller 126 may comprise a processor for executing program instructions which may be loaded from the memory. The first controller 126 may be configured to receive data from sensors in the first deposition module 101, for example pressure sensors, temperature sensors, and/or other types of sensors. The first controller 126 may be configured to control elements of the first deposition module 101 by sending control signals to, for example, gas flow control valves, heating elements, and/or water cooling elements.

In embodiments of the present invention, the first gas comprising a precursor for forming the passivation layer may be provided from a gas source 119, e.g., by opening the first valve 127 connecting the gas source 119 to the respective gas inlet 109 and via the respective injector 121 in the interior 106 of the first process chamber 102. The first heater (e.g., coils 118) may heat the interior 106 of the first process chamber 102 to a first process temperature. The first heater (e.g., coils 118) may maintain the interior 106 of the first process chamber 102 at said first process temperature. The first controller 126 may be configured for controlling the first heater. In the present example, providing the first gas in the interior 106 of the first process chamber 102 results in the formation of the passivation layer on the second part of the surface of each of the substrates 114.

After the passivation layer is provided on the second part of the surface of each of the substrates 114, the first wafer boat 113 may be lowered again, from the interior 106 of the first process chamber 102 into the first wafer boat handling space 52. Subsequently, the rotatable disc 54 may be rotated to put the first wafer boat 113 containing the substrates containing the passivation layer on the second part of the substrate surface in a position so that the wafer handling robot 80 may transfer said substrates one by one, i.e., individually, from the first wafer boat 113, through the wafer handling space 8, to a second wafer boat 63.

The second wafer boat 63 is located in the second processing zone 6 of the substrate batch processing system 4. In particular, the second wafer boat 63 is located in a second wafer boat handling space 62. Any features of any embodiment of the second processing zone 6 may be independently as correspondingly described for any embodiment of the first processing zone 5. For example, the second processing zone 6 may be structurally similar to, or the same as, the first processing zone 5 as described above and depicted in FIG. 5.

In the present example, the second wafer boat 63 is located on a rotatable disc 54 that may, after receiving the substrates from the wafer handling robot 80, be rotated so that the second wafer boat 63, containing the substrates having the passivation layer on the second part of the surface, is underneath the second deposition module 61. Subsequently, the second wafer boat 63 may be moved, e.g., lifted by a second wafer boat lift assembly, into the second process chamber of the second deposition module 61. Any features of any embodiment of the second deposition module 61 may be independently as correspondingly described for any embodiment of the first deposition module 101 as described above and depicted in FIG. 6.

The second deposition module 61 comprises a second source of the second gas comprising a precursor to the material that is to be deposited. In the present example, the second source is coupled, via a valve and an inlet, to a second gas injector. A second controller may be configured for controlling the second heater to heat the second process chamber and maintain a second process temperature in the second process chamber. The second controller may be configured for—when the substrates are present in the second process chamber—opening the valve for providing the second gas into the interior of the second process chamber for depositing said material area selectively on the first part of the surface, selectively with respect to the second part of the surface. The second controller may be configured for, after depositing the material on the first part of the surface, inducing the second heater to heat the second process chamber to an anneal temperature for annealing the thus deposited material. Such an anneal step may be a densification anneal.

After the material is deposited on the first part of the surface, or—if present—after the anneal step, the second wafer boat 63 may be moved, e.g., lowered by the second wafer boat lift assembly, back into the second wafer boat handling space 62. The rotatable disc 64 may, subsequently, be rotated for setting the second wafer boat 63 into a position so that the wafer handling robot 80 may move the substrates one by one from the second wafer boat 63 into a cassette 71 in the cassette handling space 7, from where they may be moved via the cassette storage carousel 74 and the cassette handling robots 73 to the entrance 72. The substrates may then be deemed finalized, or may be further processed into another tool, different from the substrate batch processing system 4.

Although in the above example, a specific configuration of the substrate batch processing system 4 in accordance with embodiments of the present invention is detailed, the invention is not limited to this specific configuration. For example, a single section 5, 6 may contain both the first and second deposition module, wherein the same wafer boat 113, 63 may be transferred from the first deposition module—after providing the passivation layer on the second part of the surface—into the second deposition module. This may, for example, be performed by first moving the wafer boat 113, 63, located underneath the first deposition module, from a wafer boat handling space into the first process chamber, then—after providing the passivation layer on the second part of the surface in the first deposition module—moving the wafer boat 113, 63 back into the wafer boat handling space, then rotating the rotatable disc so that the wafer boat 113, 63 is located underneath the second deposition module, and then moving the wafer boat 113, 63 into the second process chamber for depositing the material on the first part of the surface. In still another example, the wafer boat as a whole-containing the plurality of substrates-may be transferred, by a boat transfer robot, from the first processing zone containing the first deposition module to the second processing zone containing the second deposition module. Typically, both the first and second deposition module are located in the same substrate batch processing system, i.e., in the same tool, so that no transfer via cassettes is required.

It is to be understood that although preferred embodiments, specific constructions and configurations, as well as materials, have been discussed herein for devices according to the present invention, various changes or modifications in form and detail may be made without departing from the scope of this invention. Steps may be added or deleted to methods described within the scope of the present invention.

1. A substrate batch processing system for selectively forming a material on a first part of a surface of a substrate, selectively with respect to a second part of the surface of the substrate, comprising:
a first deposition module for providing a passivation layer on said second part of the surface of the substrate, comprising:
a first process chamber for receiving the substrate,
a first heater configured for heating and maintaining a first process temperature in the first process chamber,
a first gas injector configured for providing, into the first process chamber, a first gas comprising a precursor for forming a passivation layer, and
a first controller configured to cause the first deposition module to provide the passivation layer on the second part of the surface of the substrate, selectively with respect to the first part,
transfer apparatus configured for transferring, after formation of said passivation layer, the substrate from the first process chamber into a second process chamber, and
a second deposition module for depositing the material on the first part of the surface of the substrate, comprising:
the second process chamber for receiving the substrate,
a second heater configured for heating and maintaining a second process temperature in the second process chamber,
a second gas injector configured for providing, into the second process chamber, a second gas comprising a precursor to the material, and
a second controller configured to cause the second deposition module to form a layer of said material on the first part of the surface of the substrate, selectively with respect to the passivation layer on the second part.

2. The substrate batch processing system of claim 1, wherein the system is adapted so that said transfer of the substrate from the first process chamber into the second process chamber is performed through an inert atmosphere.

3. The substrate batch processing system of claim 2, wherein said inert atmosphere is a nitrogen atmosphere or a noble gas atmosphere.

4. The substrate batch processing system of claim 1, wherein the second controller is configured for-after forming said layer on the substrate-controlling the second heater so as to anneal the substrate in the second deposition module.

5. The substrate batch processing system of claim 4, wherein the anneal is a densification anneal.

6. The substrate batch processing system of claim 1, wherein the first process temperature is different from the second process temperature.

7. The substrate batch processing system of claim 6, wherein the second process temperature is higher than the first process temperature.

8. The substrate batch processing system of claim 1, wherein the first process chamber is associated with a first wafer boat for holding a plurality of substrates, and wherein the second process chamber is associated with a second wafer boat for holding a plurality of substrates, wherein the transfer apparatus comprises a wafer handling robot adapted for transferring substrates one by one, wherein the transfer apparatus is configured for, for each substrate, after providing said passivation layer on the substrate in the first process chamber, transferring the substrate individually from the first wafer boat to the second wafer boat.

9. The substrate batch processing system of claim 1, wherein the first process chamber is adapted for receiving a substrate carrier supporting a plurality of substrates and for providing the passivation layer selectively on the second part of the surface of each substrate of the plurality of substrates, wherein the transfer apparatus is configured for transferring, after formation of said passivation layer, the substrate carrier from the first process chamber into a second process chamber, and wherein the second process chamber is adapted for receiving the substrate carrier and for depositing the material selectively on the first part of the surface each substrate of the plurality of substrates.

10. The substrate batch processing system of claim 1, wherein the passivation layer is a self-assembled monolayer.

11. The substrate batch processing system of claim 1, wherein the passivation layer is a small molecule inhibitor layer.

12. The substrate batch processing system of claim 1, wherein the second deposition module is arranged for depositing the material by chemical vapor deposition.

13. The substrate batch processing system of claim 12, wherein the second deposition module is arranged for depositing the material by cyclical chemical vapor deposition.

14. The substrate batch processing system of claim 13, wherein the second deposition module is arranged for depositing the material by atomic layer deposition.

15. The substrate batch processing system of claim 1, wherein the first and second process chamber are located in a same processing tool.

16. A method for selectively forming a material on a first part of a surface of a substrate, selectively with respect to a second part of the surface of the substrate, comprising:
providing, in a first process chamber, at a first process temperature, a passivation layer on said second part of the surface of the substrate, selectively with respect to the first part, then
transferring the substrate from the first process chamber into a second process chamber, then
depositing, in the second process chamber, at a second process temperature, a layer of the material on the first part of the surface of the substrate, selectively with respect to the passivation layer on the second part.

17. A batch process comprising performing the method of claim 16 on each of a plurality of substrates.
